(19) United States
(12) Patent Application Publication
(10) Pub. No.: US 2024/0053646 A1
(43) Pub. Date: Feb. 15, 2024

(54) ARRAY SUBSTRATE AND DISPLAY PANEL

(71) Applicant: GUANGZHOU CHINA STAR OPTOELECTRONICS SEMICONDUCTOR DISPLAY TECHNOLOGY CO., LTD., Guangzhou, Guangdong (CN)

(72) Inventor: Jianqiang Sun, Guangzhou, Guangdong (CN)

(73) Assignee: GUANGZHOU CHINA STAR OPTOELECTRONICS SEMICONDUCTOR DISPLAY TECHNOLOGY CO., LTD., Guangzhou, Guangdong (CN)

(21) Appl. No.: 17/754,249

(22) PCT Filed: Mar. 15, 2022
(86) PCT No.: PCT/CN2022/080808

§ 371 Date: Mar. 28, 2022

(30) Foreign Application Priority Data
Mar. 4, 2022 (CN) 202210208989.X

(51) Int. Cl. G02F 1/1368

(52) U.S. Cl. CPC G02F 1/1368

(57) ABSTRACT

An array substrate and a display panel are disclosed. The array substrate includes a substrate, a first metal layer, a gate insulating layer, a semiconductor layer, and a second metal layer. The second metal layer includes a first block layer, a conductive layer, and a second block layer. By setting a redox potential of the first block layer to be less than a redox potential of the conductive layer, the first block layer is easier to be etched during galvanic corrosion compared with the conductive layer. Therefore, a taper angle of the second metal layer is reduced, and a tip is eliminated.

### FIELD

The present disclosure relates to a field of display technologies, and more particularly, to an array substrate and a display panel.

### BACKGROUND

In thin-film transistor (TFT) array substrates, a second metal layer of TFTs usually includes a first block layer, a conductive layer, and a second block layer sequentially stacked along a direction close to a substrate. Because the first block layer and the conductive layer have similar redox potentials, a lateral side of the first block layer and a lateral side of the conductive layer are almost etched simultaneously, resulting in a relative great taper angle (almost 90°) of the second metal layer. Furthermore, the second metal layer has a tip, leading to an overly thin passivation layer covering the second metal layer at an inclined position. Therefore, a recess of the passivation layer formed at the inclined position, contributing to breakage of a pixel electrode layer disposed on the passivation layer.

### SUMMARY

An embodiment of the present disclosure provides an array substrate and a display panel to solve following technical issues: in conventional array substrates and conventional display panels, a taper angle of a second metal layer is overly great and the second metal layer has a tip, leading to a recess of a first passivation layer formed at an inclined position, further contributing to breakage of a pixel electrode layer disposed on the passivation layer.

To solve the above issues, technical solutions provided by the present disclosure are described as follows.

The present disclosure provides an array substrate, comprising:
a substrate; and
a thin-film transistor (TFT) array layer disposed on a side of the substrate, wherein the TFT array layer comprises a first metal layer, a gate insulating layer, a semiconductor layer, and a second metal layer; and
wherein the second metal layer comprises a first block layer, a conductive layer, and a second block layer sequentially stacked along a direction close to the substrate, material of the second block layer is a Mo—Ti alloy, a redox potential of the first block layer is less than a redox potential of the conductive layer, and an absolute value of a differential between the redox potential of the first block layer and the redox potential of the conductive layer ranges from 0.15 to 0.59.

In the array substrate provided by the present disclosure, the absolute value of the differential between the redox potential of the first block layer and the redox potential of the conductive layer is greater than an absolute value of a differential between a redox potential of the second block layer and the redox potential of the conductive layer.

In the array substrate provided by the present disclosure, the first block layer comprises a first main material and a first auxiliary material, and a redox potential of the first auxiliary material is less than a redox potential of the first main material.

In the array substrate provided by the present disclosure, an absolute value of a differential between the redox potential of the first auxiliary material and the redox potential of the first main material is greater than an absolute value of a differential between the redox potential of the first main material and the redox potential of the conductive layer, the redox potential of the first main material is positive, and the redox potential of the first auxiliary electrode is negative.

The present disclosure provides an array substrate, comprising:
a substrate; and
a thin-film transistor (TFT) array layer disposed on a side of the substrate, wherein the TFT array layer comprises a first metal layer, a gate insulating layer, a semiconductor layer, and a second metal layer; and
wherein the second metal layer comprises a first block layer, a conductive layer, and a second block layer sequentially stacked along a direction close to the substrate, and a redox potential of the first block layer is less than a redox potential of the conductive layer.

In the array substrate provided by the present disclosure, an absolute value of a differential between the redox potential of the first block layer and the redox potential of the conductive layer ranges from 0.15 to 0.59.

In the array substrate provided by the present disclosure, the absolute value of the differential between the redox potential of the first block layer and the redox potential of the conductive layer is greater than an absolute value of a differential between a redox potential of the second block layer and the redox potential of the conductive layer.

In the array substrate provided by the present disclosure, the first block layer comprises a first main material and a first auxiliary material, and a redox potential of the first auxiliary material is less than a redox potential of the first main material.

In the array substrate provided by the present disclosure, an absolute value of a differential between the redox potential of the first auxiliary material and the redox potential of the first main material is greater than an absolute value of a differential between the redox potential of the first main material and the redox potential of the conductive layer, the redox potential of the first main material is positive, and the redox potential of the first auxiliary electrode is negative.

In the array substrate provided by the present disclosure, material of the conductive layer is Cu, the first main material is a Mo—Ti alloy, and the first auxiliary material is any one of Ni, Mg, Al, or Zn.

In the array substrate provided by the present disclosure, in the first block layer, a mass fraction of Mo is greater than 50%, and a mass fraction of the first auxiliary material is greater than 0 and is less than or equal to 49%.

In the array substrate provided by the present disclosure, the conductive layer comprises a second main material and a second auxiliary material, and a redox potential of the second auxiliary material is greater than a redox potential of the second main material.

In the array substrate provided by the present disclosure, an absolute value of a differential between the redox potential of the second auxiliary material and the redox potential of the second main material is greater than an absolute value of a differential between the redox potential of the first block layer and the redox potential of the second main material, the redox potential of the second main material is positive, and the redox potential of the second auxiliary material is negative.

In the array substrate provided by the present disclosure, material of the first block layer is a Mo—Ti alloy, the second main material is Cu, and the second auxiliary material is any one of Ag, Au, Pt, or Hg.

In the array substrate provided by the present disclosure, material of the second block layer is a Mo—Ti alloy.

In the array substrate provided by the present disclosure, the conductive layer comprises a second main material and a second auxiliary material, a redox potential of the second auxiliary material is greater than a redox potential of the second main material, and an absolute value of a differential between the redox potential of the second auxiliary material and the redox potential of the second main material is greater than an absolute value of a differential between a redox potential of the first main material and the redox potential of the second main material.

In the array substrate provided by the present disclosure, the first metal layer, the gate insulating layer, the semiconductor layer, and the second metal layer are sequentially stacked along a direction away from the substrate, or the semiconductor layer, the gate insulating layer, the first metal layer, and the second metal layer are sequentially stacked along the direction away from the substrate.

In the array substrate provided by the present disclosure, the array substrate comprises:
a first passivation layer covering the second metal layer; and
a pixel electrode layer disposed on a side of the first passivation layer away from the substrate, and the pixel electrode layer is electrically connected to the second metal layer by a first through-hole penetrating the first passivation layer.

In the array substrate provided by the present disclosure, the array substrate comprises:
an organic planarization layer disposed on a side of the first passivation layer away from the substrate; and
a second passivation layer disposed on a side of the organic planarization layer away from the substrate;
wherein the pixel electrode layer is disposed on a side of the second passivation layer away from the substrate, and the first through-hole penetrating the second passivation layer, the organic planarization layer, and the first passivation layer.

The present disclosure provides a display panel, comprising an opposing substrate, a liquid crystal layer, and an array substrate, wherein the opposing substrate and the array substrate are spaced apart from each other, and the liquid crystal layer is disposed between the opposing substrate and the array substrate;
wherein the array substrate comprises:
a substrate; and
a thin-film transistor (TFT) array layer disposed on a side of the substrate, and the TFT array layer comprises a first metal layer, a gate insulating layer, a semiconductor layer, and a second metal layer; and
wherein the second metal layer comprises a first block layer, a conductive layer, and a second block layer sequentially stacked along a direction close to the substrate, and a redox potential of the first block layer is less than a redox potential of the conductive layer.

### Regarding the Beneficial Effects

The present disclosure provides an array substrate and a display panel. A second metal layer includes a second block layer, a conductive layer, and a first block layer sequentially stacked. By setting a redox potential of the first block layer to be less than a redox potential of the conductive layer, the first block layer is easier to be etched during galvanic corrosion compared with the conductive layer, which is beneficial for reducing a taper angle of the second metal layer. Also, a tip of the second metal layer is eliminated, effectively improving coverage of a first passivation layer, reducing risk of breakage of a pixel electrode layer due to a recess caused by an overly thin first passivation layer at an inclined position. In addition, electric performance and reliability of TFT devices are enhanced, which reduces risk of blast due to electrostatic discharge.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which those skilled in the art can derive further figures without making any inventive efforts.

FIG. 1 is a structural schematic view showing a cross-section of a conventional array substrate.

FIG. 2 is a structural schematic view showing a cross-section of an array substrate provided by an embodiment of the present disclosure.

FIG. 3A is a structural schematic view showing a cross-section of a first TFT array layer of the array substrate provided by the embodiment of the present disclosure.

FIG. 3B is a structural schematic view showing a cross-section of a second TFT array layer of the array substrate provided by the embodiment of the present disclosure.

FIG. 4 is a first structural schematic view showing a cross-section of a second metal layer provided by an embodiment of the present disclosure.

FIG. 5 is a second structural schematic view showing a cross-section of a second metal layer provided by an embodiment of the present disclosure.

FIG. 6 is a third structural schematic view showing a cross-section of a second metal layer provided by an embodiment of the present disclosure.

FIG. 7 is a structural schematic view showing a cross-section of another array substrate provided by an embodiment of the present disclosure.

FIG. 8 is a flowchart showing a method of manufacturing an array substrate provided by an embodiment of the present disclosure.

### REFERENCE NUMBERS OF DRAWINGS

tip 1a, breakage position 1b;
substrate 10, TFT array layer 20, first metal layer 201, gate insulating layer 202, semiconductor layer 203, second metal layer 204, source/drain electrode insulating layer 205, first passivation layer 30, pixel electrode layer 40, organic planarization layer 50, second passivation layer 60;
first block layer 2041, conductive layer 2042, second block layer 2043;
first through-hole 301, second through-hole 302.

### DETAILED DESCRIPTION

Hereinafter preferred embodiments of the present disclosure will be described with reference to the accompanying drawings to exemplify the embodiments of the present disclosure can be implemented, which can fully describe the technical contents of the present disclosure to make the technical content of the present disclosure clearer and easy to understand. However, the described embodiments are only some of the embodiments of the present disclosure, but not all of the embodiments. All other embodiments obtained by those skilled in the art based on the embodiments of the present disclosure without creative efforts are within the scope of the present disclosure. Embodiments, which are based on the embodiments of the present disclosure, obtained by those skilled in the art without making any inventive efforts are within the scope of protection defined by the present disclosure. It should be noted that described embodiments are merely used to construct the present disclosure and are not intended to limit the present disclosure. In the present disclosure, unless further description is made, terms such as “top” and “bottom” usually refer to a top of a device and a bottom of a device in an actual process or working status, and specifically, to the orientation as shown in the drawings. Terms such as “inside” and “outside” are based on an outline of a device.

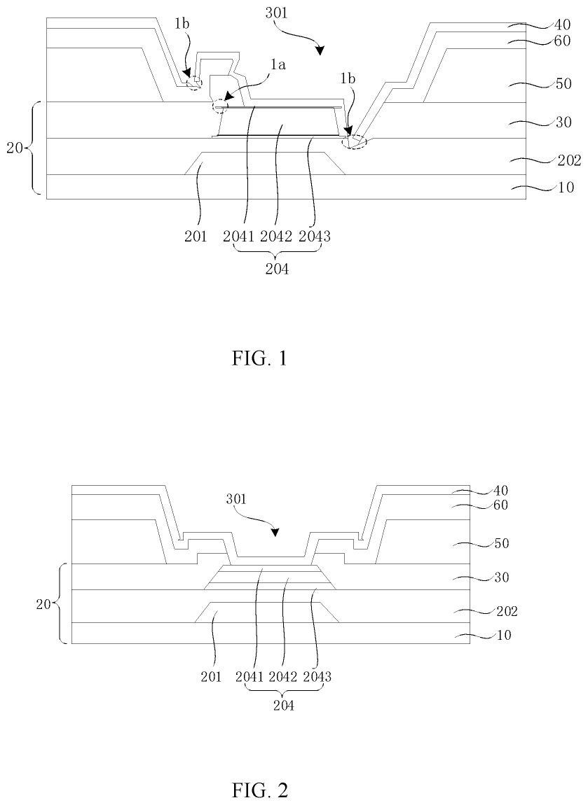

Please refer to FIG. 1, a structural schematic view showing a cross-section of a conventional array substrate is provided. A thin-film transistor (TFT) comprises a substrate 10 and a TFT array layer 20. The TFT array layer 20 includes a first metal layer 201, a gate insulating layer 202, a semiconductor layer (not shown), and a second metal layer 204. A first passivation layer 30 is disposed on a side of the second metal layer 204 away from the substrate 10. A pixel electrode layer 40 is disposed on a side of the passivation layer 30 away from the substrate 10. The second metal layer 204 usually includes three metal layers including a first block layer 2041, a conductive layer 2042, and a second block layer 2043.

It should be noted that when two metals or alloys are connected and conducted to each other in an electrolyte solution, corrosion of a metal or an alloy having a relatively great electric potential is accelerated, and a metal or an alloy having a relatively less electric potential is protected and is difficult to be corroded. Because the first block layer 2041 and the conductive layer 2042 have very similar redox potentials, a lateral side of the first block layer 2041 and a lateral side of the conductive layer 2042 are almost etched simultaneously, resulting in a relative great taper angle (almost 90°) of the second metal layer 204. Furthermore, the second metal layer 204 has a tip, leading to a recess of the passivation layer 30 formed at an inclined position, further contributing to breakage of the pixel electrode layer 40, as shown in a breakage position 1b in FIG. 1.

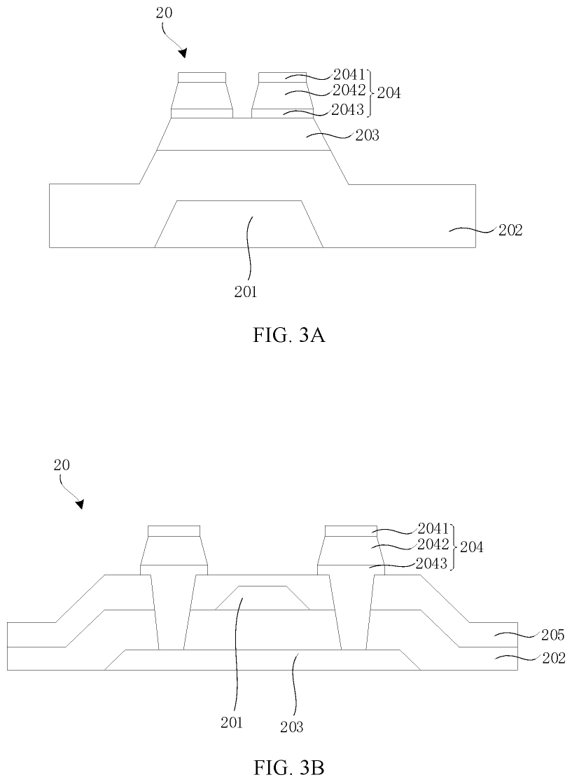

Therefore, an embodiment of the present disclosure provides an array substrate, as shown in FIG. 2 and FIGS. 3A to 3B. FIG. 2 is a structural schematic view showing a cross-section of the array substrate provided by the embodiment of the present disclosure. FIG. 3A is a structural schematic view showing a cross-section of a TFT array layer of the array substrate provided by the embodiment of the present disclosure. FIG. 3B is a structural schematic view showing a cross-section of a second TFT array layer of the array substrate provided by the embodiment of the present disclosure.

The array substrate comprises a substrate 10 and a TFT array layer 20. The TFT array layer 20 is disposed on a side of the substrate 10. The TFT array layer 20 includes a plurality of TFTs. The TFT layer 20 includes a first metal layer 201, a gate insulating layer 202, a semiconductor layer 203, and a second metal layer 204. As shown in FIG. 3A, the TFTs may be bottom-gate TFTs. Specifically, the first metal layer 201, the gate insulating layer 202, the semiconductor layer 203, and the second metal layer 204 are sequentially stacked along a direction away from the substrate 10. A shown in FIG. 3B, the TFTs may also be top-gate TFTs. Specifically, the semiconductor layer 203, the gate insulating layer 202, the first metal layer 201, and the second metal layer 204 are sequentially stacked along the direction away from the substrate 10. The TFT array layer 20 further includes a source/drain electrode insulating layer 205. The source/drain electrode insulating layer 205 covers the first metal layer 201 and the gate insulating layer 202. The source/drain electrode insulating layer 205 includes a source and a drain. The source is electrically connected to the semiconductor layer 203 by a through-hole penetrating the source/drain electrode insulating layer 205. The drain is electrically connected to the semiconductor layer 203 by another through-hole penetrating the source/drain electrode insulating layer 205.

Furthermore, the array substrate includes a first passivation layer 30 and a pixel electrode layer 40. The first passivation layer 30 covers the second metal layer 204. The pixel electrode layer 40 is disposed on a side of the passivation layer 30 away from the substrate 10. The pixel electrode layer 40 is electrically connected to the second metal layer 204 by a first through-hole 301 penetrating the first passivation layer 30.

The second metal layer 204 includes three metal layers. Specifically, the second metal layer 204 includes a second block layer 2043, a conductive layer 2042, and a first block layer 2041 sequentially stacked. It should be understood that, in the present embodiment, a redox potential of the first block layer 2041 is set to be less than a redox potential of the conductive layer 2042. Galvanic corrosion occurs when two metals or two alloys are connected and conductive to each other. That is, corrosion of a metal or an alloy having a relatively great electric potential is accelerated, and a metal or an alloy having a relatively less electric potential is protected and is difficult to be corroded. Therefore, the first block layer 2041 is easier to be etched during galvanic corrosion compared with the conductive layer 2042. The first block layer 2041 is first consumed. Compared with conventional technologies, in the present embodiment, a taper angle of the second metal layer 204 is significantly reduced, and a tip is eliminated. When the first passivation layer 30 is manufactured in sequential processes, coverage of the first passivation 30 is improved, thereby preventing breakage of the pixel electrode layer 40 due to a recess caused by an overly thin first passivation layer 30 at an inclined position. In addition, since coverage of the first passivation 30 is improved, moisture and ions in ambient air are effectively prevented from entering the TFT array layer 20. Therefore, electric performance and reliability of TFT devices are enhanced, and risk of blast due to electrostatic discharge is reduced.

Specifically, to ensure that the first block layer 2041 can be etched faster compared with the conductive layer 2042, in the present embodiment, an absolute value of a differential between the redox potential of the first block layer 2041 and the redox potential of the conductive layer 2042 ranges from 0.15 to 0.59.

Furthermore, the absolute value of the differential between the redox potential of the first block layer 2041 and the redox potential of the conductive layer 2042 is greater than an absolute value of a differential between a redox potential of the second block layer 2043 and the redox potential of the conductive layer 2042. Therefore, the redox potential of the first block layer 2041 is far less than the redox potential of the conductive layer 2042, which is beneficial for further reducing a taper angle of the second metal layer 204 and eliminating a tip.

In the present embodiment, a taper angle of the second metal layer 204 is less than 60°. In conventional technologies, a taper angle of the second metal layer 204 is greater than 80°. Therefore, a taper angle is significantly reduced in the present embodiment, thereby satisfying requirements.

Specifically, the substrate 10 is made of a rigid substrate or any appropriate flexible insulating material. The substrate 10 may be transparent, translucent, or opaque. Optionally, the substrate 10 may be a glass substrate. The first metal layer 201 is disposed on a side of the substrate 10. The first metal layer 201 includes a gate. The gate may include a single layer or multiple layers of Au, Ag, Cu, Ni, Pt, Pd, Al, Mo, or Cr. Alternatively, the gate may include an Al—Nd alloy or a Mo—W alloy. The gate insulating layer 202 covers the first metal layer 201 and the substrate 10. The gate insulating layer 202 may be made of an insulating inorganic layer such as silicon oxide or silicon nitride, or may be made of an insulating organic layer. The semiconductor layer 203 is disposed on a side of the gate insulating layer 202 away from the substrate 10. Material of the semiconductor layer 203 includes indium gallium zinc oxide (IGZO). The second metal layer 204 is disposed on a side of the semiconductor layer 203 away from the substrate. The second metal layer 204 includes a source and a drain. The pixel electrode layer 40 is electrically connected to the drain by the first through-hole 301. The first passivation layer 30 may be made of an inorganic layer such as silicon oxide or silicon nitride, or may be made of an organic layer.

Optionally, in the present embodiment, an electrolyte solution used during galvanic corrosion may be a capric acid solution. Of course, the electrolyte solution used during galvanic corrosion may also be other electrolyte solutions, and is not limited by the present embodiment.

It should be noted that, in conventional technologies, the first block layer 2041 and the conductive layer 2042 have similar redox potentials, and the first block layer 2041 and the second block layer 2043 have a same material. That is, the first block layer 2041 and the second block layer 2043 have a same redox potential, meaning that the redox potential of the first block layer 2041 and the redox potential of the second block layer 2043 are close to the redox potential of the conductive layer 2042.

To solve the technical issues disclosed by the present disclosure, it is necessary to make the redox potential of the first block layer 2041 less than the redox potential of the conductive layer 2042. Furthermore, it is necessary to increase the absolute value of the differential between the redox potential of the first block layer 2041 and the redox potential of the conductive layer 2042.

Therefore, the present disclosure provides various types of embodiments to achieve the above goal. The embodiments are described in detail as follows.

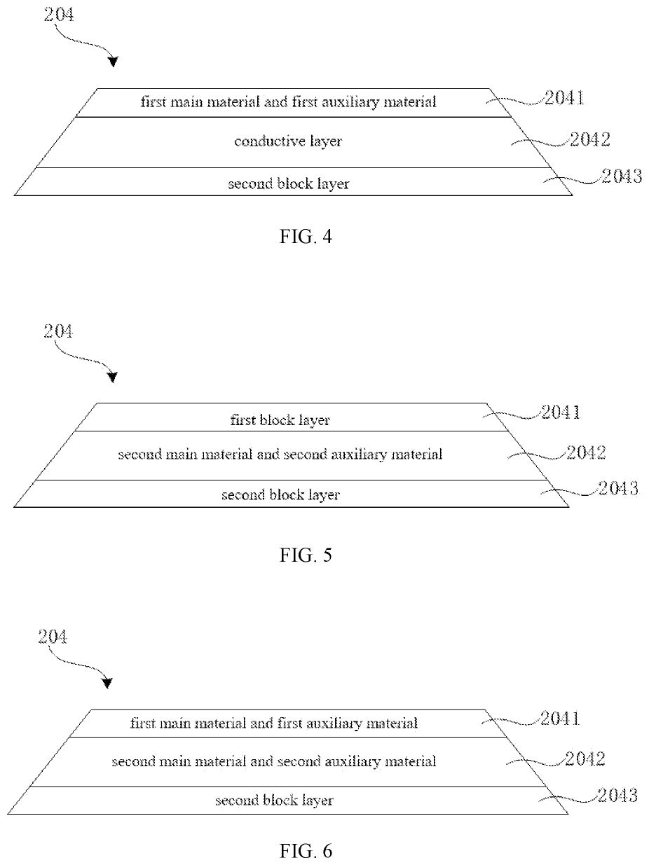

Please refer to FIG. 4, a first structural schematic view showing a cross-section of the second metal layer provided by an embodiment of the present disclosure is provided. In one embodiment, to achieve the above goal, the redox potential of the first block layer 2041 is reduced, and the redox potential of the second block layer 2042 remains unchanged. Specifically, the first block layer 2041 includes a first main material and a first auxiliary material. A redox potential of the first auxiliary material is less than a redox potential of the first main material.

It should be noted that the first main material is a material of a conventional first block layer 2041, and the first auxiliary material of an additional material is added to the first main material. The first auxiliary material is only configured to adjust an entire redox potential of the first block layer 2041, and does not much affect properties and functions of the first block layer 2041.

It should be understood that, in the present embodiment, the first auxiliary material is added to the first main material. Since the redox potential of the first auxiliary material is less than the redox potential of the first main material, the entire redox potential of the first block layer 2041 is reduced. Furthermore, the redox potential of the first main material is close to the redox potential of the conductive layer 2042. The adjusted redox potential of the first block layer 2041 is far less than the redox potential of the conductive layer 2042. Therefore, the first block layer 2041 is easier to be etched during galvanic corrosion compared with the conductive layer 2042, which is beneficial for reducing a taper angle of the second metal layer 204 and eliminating a tip. Therefore, coverage of the first passivation layer 30 is effectively improved, and breakage of pixel electrode layer 40 due to a recess caused by the overly thin first passivation layer 30 at an inclined position is prevented. In addition, electric performance and reliability of TFT devices are reduced, thereby reducing risk of blast due to electrostatic discharge.

Furthermore, an absolute value of a differential between the redox potential of the first auxiliary and the redox potential of the first main material is greater than an absolute value of a differential between the redox potential of the first main material and the redox potential of the conductive layer 2042. In the present embodiment, the redox potential of the first main material is positive, and the redox potential of the first auxiliary is negative. By adding the first auxiliary material having the negative redox potential into the first main material, the redox potential of the first block layer 2041 can be significantly reduced.

Specifically, material of the conductive layer 2042 is Cu. The first main material is a Mo—Ti alloy. The first auxiliary is any one of Ni, Mg, Al, or Zn. Optionally, the first auxiliary material is Ni. Generally, a redox potential of a Mo—Ti alloy is 0.29 EO/V, a redox potential of Cu is 0.34 EO/V, and a redox potential of Ni is −0.25 EO/V. Therefore, after a metal element of Ni is added, the redox potential of the first block layer 2041 is significantly reduced.

Furthermore, in the first block layer 2041, a mass fraction of Mo is greater than 50%, and a mass fraction of the first auxiliary material is greater than 0 and is less than or equal to 49%. Optionally, in the present embodiment, mass fractions of Mo, Ti, and Ni are 61%, 13%, and 26%, respectively.

Specifically, the material of the second block layer 2043 and the first main material are a same. In the present embodiment, the material of the second block layer 2043 is a Mo—Ti alloy, and mass fractions of Mo and Ti in the Mo—Ti alloy are 50% and 50%, respectively.

Please refer to FIG. 5, a second structural schematic view showing a cross-section of the second metal layer provided by an embodiment of the present disclosure is provided. A difference between the present embodiment and the above embodiment is: in the present embodiment, to achieve the above goal, the redox potential of the conductive layer 2042 is increased, and the redox potential of the first block layer 2041 remains unchanged. Specifically, the conductive layer 2042 includes a second main material and a second auxiliary material. A redox potential of the second auxiliary material is greater than a redox potential of the second main material.

Similarly, the second main material is a material used in a conventional conductive layer 2042, and the second auxiliary material is an additional material is added to the second main material. The second auxiliary is only configured to adjust an entire redox potential of the conductive layer 2042, and does not much affect properties and functions of the conductive layer 2042.

Similarly, in the present embodiment, the first auxiliary material is added to the second main material. Since the redox potential of the second auxiliary material is greater than the redox potential of the second main material, the entire redox potential of the conductive layer 2042 is increased. Furthermore, because the redox potential of the second main material is close to the redox potential of the first block layer 2041, the adjusted redox potential of the first block layer 2041 is far less than the redox potential of the conductive layer 2042. Therefore, the first block layer 2041 is easier to be etched during galvanic corrosion compared with the conductive layer 2042, which is beneficial for reducing a taper angle of the second metal layer 204 and eliminating a tip. As such, coverage of the first passivation layer 30 is effectively improved, and breakage of the pixel electrode layer 40 due to a recess caused by the overly thin first passivation layer 30 at an inclined position is prevented. In addition, electric performance and reliability of TFT devices are enhanced, and risk of blast due to electrostatic discharge is reduced.

Furthermore, an absolute value of a differential between the redox potential of the second auxiliary material and the redox potential of the second main material is greater than an absolute value of a differential between the redox potential of the first block layer 2041 and the redox potential of the second main material. In the present embodiment, the redox potential of the second material is positive, the redox potential of the first auxiliary material is positive, and the redox potential of the first auxiliary material is far greater than the redox potential of the second main material.

Specifically, the material of the first block layer 2041 is a Mo—Ti alloy, the second main material is Cu, and the second auxiliary material is any one of Ag, Au, Pt, or Hg. Optionally, the second auxiliary material is Ag. Generally, a redox potential of a Mo—Ti alloy is 0.29 EO/V, a redox potential of Cu is 0.34 EO/V, and a redox potential of Ag is 1.987 EO/V. Therefore, after a metal element of Ag is added, the redox potential of the conductive layer 2042 is significantly increased.

Please refer to FIG. 6, a third structural schematic view showing a cross-section of the second metal layer provided by an embodiment of the present disclosure is provided. A Difference between the present embodiment and the above two embodiments is: the present embodiment is a combination of the above two embodiments. In the present embodiment, to achieve the above goal, the redox potential of the first block layer 2041 is reduced, and the redox potential of the conductive layer 2042 is increased. Specifically, the first block layer 2041 includes the first main material and the first auxiliary material. The redox potential of the first auxiliary material is less than the redox potential of the first main material. Furthermore, the absolute value of the differential between the redox potential of the first auxiliary material and the first main material is greater than the absolute value of the differential between the redox potential of the first main material and the redox potential of the conductive layer 2042. The conductive layer 2042 includes the second main material and the second auxiliary material. The redox potential of the second auxiliary material is greater than the redox potential of the second main material. Furthermore, the absolute value of the differential between the redox potential of the second auxiliary material and the redox potential of the second main material is greater than an absolute value of the differential between the redox potential of the first main material and the redox potential of the second main material.

Similarly, the first auxiliary material is added to the first main material, and the second auxiliary material is added to the second main material. Since the redox potential of the first auxiliary material is less than the redox potential of the first main material, and the redox potential of the second auxiliary material is greater than the redox potential of the second main material, the redox potential of the first block layer 2041 is reduced and the redox potential of the conductive layer 2042 is increased. Furthermore, because the redox potential of the first main material is close to the redox potential of the second main material, the differential between the redox potential of the first block layer 2041 and the redox potential of the conductive layer 2042 can be further increased. Therefore, the first block layer 2041 is easier to be etched during galvanic corrosion compared with the conductive layer 2042. As such, a taper angle of the second metal layer 204 is further reduced, and breakage of the pixel electrode layer 40 due to a recess caused by the overly thin first passivation layer 30 at an inclined position is prevented. In addition, electric performance and reliability of TFT devices are enhanced, and risk of blast due to electrostatic discharge is reduced.

Specifically, the material of the conductive layer 2042 is Cu, the first main material is a Mo—Ti alloy, and the material of the first auxiliary material is any one of Ni, Mg, or Zn. Optionally, the first auxiliary material is Ni, the first main material is a Mo—Ti alloy, the second main material is Cu, and the second auxiliary material is any one of Ag, Au, Pt, or Hg. Optionally, the second auxiliary material is Ag.

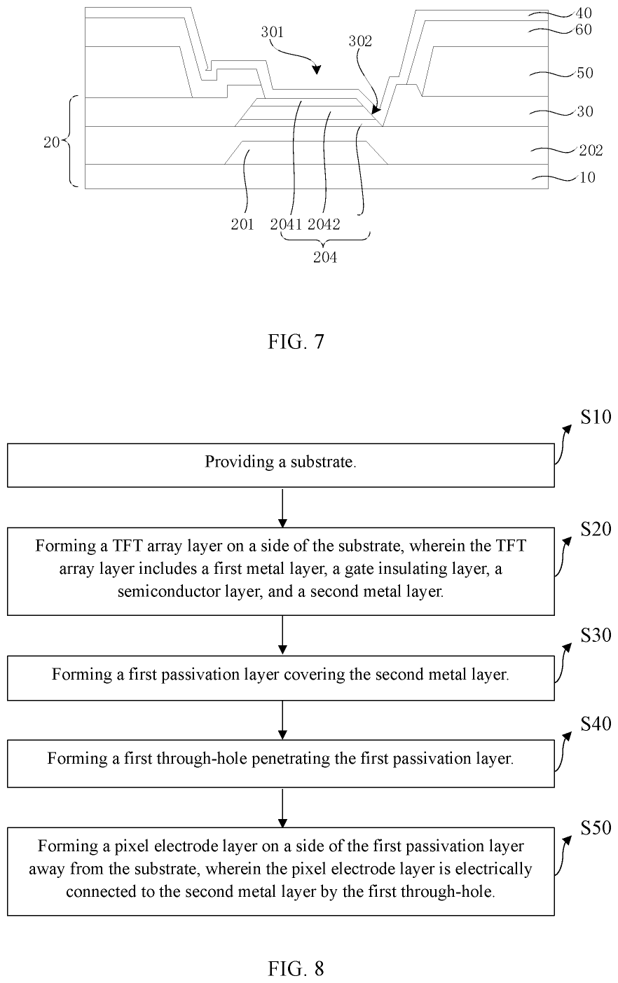

Please refer to FIG. 7, a structural schematic view showing a cross-section of another array substrate provided by an embodiment of the present disclosure is provided. In the present embodiment, the first passivation layer 30 may also have an out-cell structure. Specifically, a second through-hole 302 is defined in the first passivation layer 30. The second through-hole 302 is defined close to the second metal layer 204 and is spaced apart from the second metal layer 204. Because the second metal layer 204 has an overly large taper angle in conventional technologies, the second through-hole 302 has a relatively inclined surface, resulting in breakage of the pixel electrode layer 40 at an inclined position of the through-hole 302. In the present embodiment, the second metal layer 204 has a relatively small taper angle. Therefore, the second through-hole 302 has a relatively flat surface, which can reduce risk of breakage of the pixel electrode layer 40 at an inclined position of the second through-hole 302.

Furthermore, the array substrate further includes an organic planarization layer 50 and a second passivation layer 60. The organic planarization layer 50 is disposed on a side of the first passivation layer 30 away from the substrate 10. The second passivation layer 60 is disposed on a side of the organic planarization layer 50 away from the substrate 10. The pixel electrode layer 40 is disposed on a side of the second passivation layer 60 away from the substrate. The first through-hole 301 penetrates the second passivation layer 60, the organic planarization layer 50, and the first passivation layer 30.

Specifically, material of the planarization layer 50 may be an organosiloxane resin. The second passivation layer 60 and the first passivation layer 30 may have a same material.

An embodiment of the present disclosure further provides a display panel, including an opposing substrate, a liquid crystal layer, and the array substrate of the above embodiments. The opposing substrate and the array substrate are spaced apart from each other. The liquid crystal layer is disposed between the opposing substrate and the array substrate.

Please refer to FIG. 0.8, a flowchart showing a method of manufacturing an array substrate provided by an embodiment of the present disclosure is provided. An embodiment of the present disclosure further provides a method of manufacturing an array substrate, including following steps:
step S10, providing a substrate 10;
step S20, forming a TFT array layer 20 on a side of the substrate 10, wherein the TFT array layer 20 includes a first metal layer 201, a gate insulating layer 202, a semiconductor layer 203, and a second metal layer 204;
step S30, forming a first passivation layer 30 covering the second metal layer 204;
step S40: forming a first through-hole 301 penetrating the first passivation layer 30; and
step S50, forming a pixel electrode layer 40 on a side of the first passivation layer 30 away from the substrate 10, wherein the pixel electrode layer 40 is electrically connected to the second metal layer 204 by the first through-hole 301.

Specifically, the TFT array layer 20 includes a plurality of TFTs. The TFTs as bottom-gate TFTs are taken as an example for illustration. The step S20 includes following steps:
step S201, forming the first metal layer 201 on the substrate 10;
step S202, forming the gate insulating layer 202 covering the first metal layer 201;
step S203, forming the semiconductor layer 203 on the gate insulating layer 202; and
step S204, forming the second metal layer 204 on the semiconductor layer 203.

Furthermore, the step S204 includes following steps:
step S2041, sequentially coating material of a block layer 2043, material of a conductive layer 2042, and material of a first block layer 2041 on the semiconductor layer 203; and
step S2042, performing exposure, developing, and etching processes on the material of the second block layer 2043, the material of the conductive layer 2042, and the material of the first block layer 2041 to form the second metal layer 204.

Specifically, in the step S2041, in one embodiment, the first block layer 2041 includes a first main material and a first auxiliary material. The material of the conductive layer 2042 is Cu, the material of the second block layer 2043 is a Mo—Ti alloy, the first main material is a Mo—Ti alloy, and the first auxiliary material is any one of Ni, Mg, Al, or Zn. Optionally, the first auxiliary material is Ni.

In another embodiment, the conductive layer 2042 includes a second main material and a second auxiliary material. The material of the first block layer 2041 and the material of the second block layer 2043 are Mo—Ti alloys, the second main material is Cu, and the second auxiliary material is any one of Ag, Au, Pt, or Hg. Optionally, the second auxiliary material is Ag.

In yet another embodiment, the first block layer 2041 includes the first main material and the first auxiliary material. The conductive layer 2042 includes the second main material and the second auxiliary material. The first main material and the material of the second block layer 2043 are Mo—Ti alloys. The first auxiliary material is any one of Ni, Mg, Al, or Zn. Optionally, the first auxiliary material is Ni, and the second auxiliary material is any one of Ag, Au, Pt, or Hg. Optionally, the second auxiliary material is Ag.

Specifically, in the step S2042, a wet-etching method can be applied, and an etchant may be an electrolyte solution.

Regarding the beneficial effects: the present disclosure provides an array substrate and a display panel. A second metal layer includes a second block layer, a conductive layer, and a first block layer sequentially stacked. By setting a redox potential of the first block layer to be less than a redox potential of the conductive layer, the first block layer is easier to be etched during galvanic corrosion compared with the conductive layer, which is beneficial for reducing a taper angle of the second metal layer. Also, a tip of the second metal layer is eliminated, effectively improving coverage of a first passivation layer, reducing risk of breakage of a pixel electrode layer due to a recess caused by an overly thin first passivation layer at an inclined position. In addition, electric performance and reliability of TFT devices are enhanced, which reduces risk of blast due to electrostatic discharge.

In summary, the present disclosure has been described with preferred embodiments thereof. The preferred embodiments are not intended to limit the present disclosure, and it is understood that many changes and modifications to the described embodiments can be carried out without departing from the scope and the spirit of the disclosure that is intended to be limited only by the appended claims.

What is claimed is:

1. An array substrate, comprising:
a substrate; and
a thin-film transistor (TFT) array layer disposed on a side of the substrate, wherein the TFT array layer comprises a first metal layer, a gate insulating layer, a semiconductor layer, and a second metal layer; and
wherein the second metal layer comprises a first block layer, a conductive layer, and a second block layer sequentially stacked along a direction close to the substrate, material of the second block layer is a Mo—Ti alloy, a redox potential of the first block layer is less than a redox potential of the conductive layer, and an absolute value of a differential between the redox potential of the first block layer and the redox potential of the conductive layer ranges from 0.15 to 0.59.

2. The array substrate of claim 1, wherein the absolute value of the differential between the redox potential of the first block layer and the redox potential of the conductive layer is greater than an absolute value of a differential between a redox potential of the second block layer and the redox potential of the conductive layer.

3. The array substrate of claim 2, wherein the first block layer comprises a first main material and a first auxiliary material, and a redox potential of the first auxiliary material is less than a redox potential of the first main material.

4. The array substrate of claim 3, wherein an absolute value of a differential between the redox potential of the first auxiliary material and the redox potential of the first main material is greater than an absolute value of a differential between the redox potential of the first main material and the redox potential of the conductive layer, the redox potential of the first main material is positive, and the redox potential of the first auxiliary electrode is negative.

5. An array substrate, comprising:
a substrate; and
a thin-film transistor (TFT) array layer disposed on a side of the substrate, wherein the TFT array layer comprises a first metal layer, a gate insulating layer, a semiconductor layer, and a second metal layer; and
wherein the second metal layer comprises a first block layer, a conductive layer, and a second block layer sequentially stacked along a direction close to the substrate, and a redox potential of the first block layer is less than a redox potential of the conductive layer.

6. The array substrate of claim 5, wherein an absolute value of a differential between the redox potential of the first block layer and the redox potential of the conductive layer ranges from 0.15 to 0.59.

7. The array substrate of claim 6, wherein the absolute value of the differential between the redox potential of the first block layer and the redox potential of the conductive layer is greater than an absolute value of a differential between a redox potential of the second block layer and the redox potential of the conductive layer.

8. The array substrate of claim 7, wherein the first block layer comprises a first main material and a first auxiliary material, and a redox potential of the first auxiliary material is less than a redox potential of the first main material.

9. The array substrate of claim 8, wherein an absolute value of a differential between the redox potential of the first auxiliary material and the redox potential of the first main material is greater than an absolute value of a differential between the redox potential of the first main material and the redox potential of the conductive layer, the redox potential of the first main material is positive, and the redox potential of the first auxiliary electrode is negative.

10. The array substrate of claim 9, wherein material of the conductive layer is Cu, the first main material is a Mo—Ti alloy, and the first auxiliary material is any one of Ni, Mg, Al, or Zn.

11. The array substrate of claim 10, wherein in the first block layer, a mass fraction of Mo is greater than 50%, and a mass fraction of the first auxiliary material is greater than 0 and is less than or equal to 49%.

12. The array substrate of claim 11, wherein the conductive layer comprises a second main material and a second auxiliary material, and a redox potential of the second auxiliary material is greater than a redox potential of the second main material.

13. The array substrate of claim 12, wherein an absolute value of a differential between the redox potential of the second auxiliary material and the redox potential of the second main material is greater than an absolute value of a differential between the redox potential of the first block layer and the redox potential of the second main material, the redox potential of the second main material is positive, and the redox potential of the second auxiliary material is positive.

14. The array substrate of claim 13, wherein material of the first block layer is a Mo—Ti alloy, the second main material is Cu, and the second auxiliary material is any one of Ag, Au, Pt, or Hg.

15. The array substrate of claim 5, wherein material of the second block layer is a Mo—Ti alloy.

16. The array substrate of claim 6, wherein the conductive layer comprises a second main material and a second auxiliary material, a redox potential of the second auxiliary material is greater than a redox potential of the second main material, and an absolute value of a differential between the redox potential of the second auxiliary material and the redox potential of the second main material is greater than an absolute value of a differential between a redox potential of a first main material and the redox potential of the second main material.

17. The array substrate of claim 5, wherein the first metal layer, the gate insulating layer, the semiconductor layer, and the second metal layer are sequentially stacked along a direction away from the substrate, or the semiconductor layer, the gate insulating layer, the first metal layer, and the second metal layer are sequentially stacked along the direction away from the substrate.

18. The array substrate of claim 5, wherein the array substrate comprises:
a first passivation layer covering the second metal layer; and
a pixel electrode layer disposed on a side of the first passivation layer away from the substrate, and the pixel electrode layer is electrically connected to the second metal layer by a first through-hole penetrating the first passivation layer.

19. The array substrate of claim 18, wherein the array substrate comprises:
an organic planarization layer disposed on a side of the first passivation layer away from the substrate; and
a second passivation layer disposed on a side of the organic planarization layer away from the substrate;
wherein the pixel electrode layer is disposed on a side of the second passivation layer away from the substrate, and the first through-hole penetrating the second passivation layer, the organic planarization layer, and the first passivation layer.

20. A display panel, comprising an opposing substrate, a liquid crystal layer, and the array substrate, wherein the opposing substrate and the array substrate are spaced apart from each other, and the liquid crystal layer is disposed between the opposing substrate and the array substrate;
wherein the array substrate comprises:
a substrate; and
a thin-film transistor (TFT) array layer disposed on a side of the substrate, and the TFT array layer comprises a first metal layer, a gate insulating layer, a semiconductor layer, and a second metal layer; and
wherein the second metal layer comprises a first block layer, a conductive layer, and a second block layer sequentially stacked along a direction close to the substrate, and a redox potential of the first block layer is less than a redox potential of the conductive layer.
